(19) United States
(12) Patent Application Publication
(10) Pub. No.: US 2024/0363912 A1
(43) Pub. Date: Oct. 31, 2024

(54) BATTERY CONTROL APPARATUS AND BATTERY CONTROL METHOD

(71) Applicant: NGK INSULATORS, LTD., Nagoya-shi (JP)

(72) Inventor: Sangji YOON, Nagoya-shi (JP)

(21) Appl. No.: 18/765,458

(22) Filed: Jul. 8, 2024

Related U.S. Application Data
(63) Continuation of application No. PCT/JP2022/043363, filed on Nov. 24, 2022.

(30) Foreign Application Priority Data
Jan. 21, 2022 (JP) 2022-008150

(51) Int. Cl. H01M 10/42; G01R 31/3835; H01M 10/48; H02J 7/00

(52) U.S. Cl. CPC H01M 10/425; G01R 31/3835; H01M 10/48; H02J 7/0048; H01M 2010/4271

(57) ABSTRACT

A battery control apparatus includes a voltage detection unit which detects an open-circuit voltage of a secondary battery when the secondary battery is discharged after being charged and a control unit which estimates an amount of decrease in the open-circuit voltage due to a memory effect on the basis of a charge and discharge history of the secondary battery.

### CROSS-REFERENCE TO RELATED APPLICATION

This application is a continuation application of PCT/JP2022/043363 filed on Nov. 24, 2022, which claims the benefit of priority of Japanese Patent Application No. 2022-008150 filed on Jan. 21, 2022, the entire contents of which are incorporated herein by reference.

### BACKGROUND OF THE INVENTION

### 1. Field of the Invention

The present invention relates to an apparatus and a method for controlling a secondary battery.

### 2. Description of Related Art

Nickel hydrogen batteries and the like have been widely used as inexpensive and safe secondary batteries. In recent years, a zinc secondary battery having a high energy density and a high degree of safety has been developed as a secondary battery to replace a conventional lithium-ion battery. Such secondary batteries are more prone to a memory effect than lithium-ion batteries. For this reason, the secondary batteries are known to suffer decrease in battery voltage due to the memory effect if the secondary batteries are repeatedly charged and discharged in a state with a depth of discharge greater than 0%.

As for suppression of the memory effect, for example, the technique in Patent Literature 1 (Japanese Patent Laid-Open No. 2017-41393) is known. Patent Literature 1 discloses a nickel hydrogen battery which uses, as a positive electrode active material, H₂NiP₂O₇ having a crystal structure composed of a NiO₆ octahedron and a PO₄ tetrahedron to suppress occurrence of the memory effect.

The nickel hydrogen battery described in Patent Literature 1 can suppress occurrence of the memory effect and curb decrease in battery voltage but cannot completely prevent decrease in the battery voltage. For this reason, accurate estimation of a depth of discharge from the battery voltage is difficult, which may cause decrease in secondary battery control accuracy.

The present invention has been made in view of the above-described problem, and has its object to provide a technique capable of controlling a secondary battery with high accuracy even if a memory effect occurs.

### SUMMARY OF THE INVENTION

A battery control apparatus according to the present invention includes a voltage detection unit which detects an open-circuit voltage of a secondary battery when the secondary battery is discharged after being charged and a control unit which estimates an amount of decrease in the open-circuit voltage due to a memory effect on the basis of a charge and discharge history of the secondary battery.

A battery control method according to the present invention includes storing a charge and discharge history of a second battery, detecting an open-circuit voltage of the secondary battery when the secondary battery is discharged after being charged, estimating an amount of decrease in the open-circuit voltage due to a memory effect on the basis of the charge and discharge history of the secondary battery, and controlling the secondary battery on the basis of the estimated amount of decrease in the open-circuit voltage.

According to the present invention, it is possible to control a secondary battery with high accuracy even if a memory effect occurs.

### BRIEF DESCRIPTION OF DRAWINGS

FIG. 1 is a schematic configuration diagram of a battery control apparatus according to one embodiment of the present invention.

FIG. 2 is a chart showing an outline of decrease in battery voltage due to a memory effect.

FIG. 3 is a flowchart showing the flow of a process by the battery control apparatus according to the one embodiment of the present invention.

FIG. 4 is a flowchart showing details of an OCV calculation process.

### DESCRIPTION OF PREFERRED EMBODIMENTS

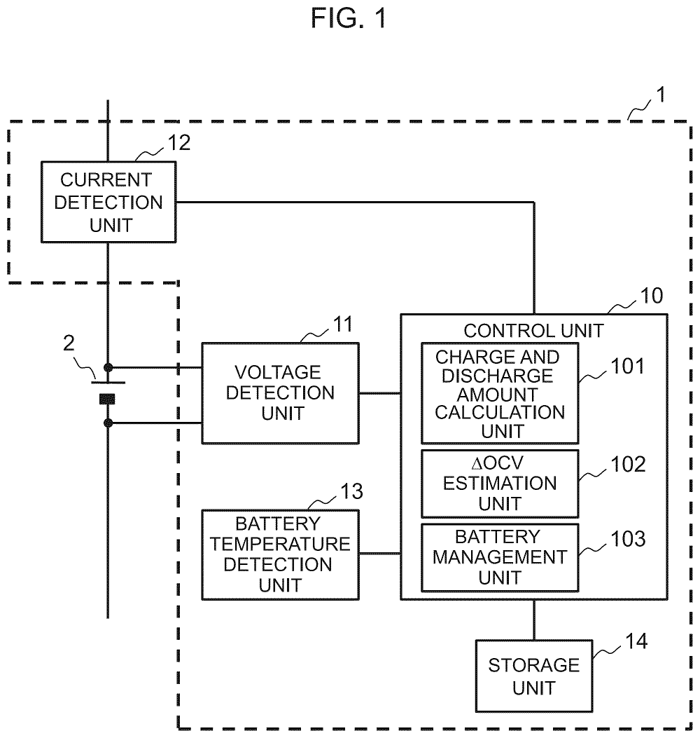

FIG. 1 is a schematic configuration diagram of a battery control apparatus according to one embodiment of the present invention. A battery control apparatus 1 shown in FIG. 1 is used connected to a battery 2 to control the battery 2. The battery 2 is a secondary battery which is chargeable and dischargeable. For example, a zinc secondary battery using nickel hydroxide for a positive electrode and zinc for a negative electrode, a nickel hydrogen battery, or the like can be used as the battery 2. Note that the battery 2 may be a cell or a cell module which is a combination of a plurality of cells.

The present embodiment will describe a case where a secondary battery prone to a memory effect is used as the battery 2. A memory effect refers to a phenomenon in which a battery voltage decreases rapidly while a secondary battery is discharging at around a battery voltage at the end of a last discharge if so-called top-up charging that repeats charge and discharge while a depth of discharge of the secondary battery is an intermediate depth between a maximum value and a minimum value is performed. Such a memory effect is known to occur prominently in secondary batteries such as a zinc secondary battery or a nickel hydrogen battery using nickel for a positive electrode.

Even if a memory effect occurs in the battery 2, the battery control apparatus 1 according to the present embodiment estimates an amount of decrease in battery voltage due to the memory effect by the method to be described below and corrects the battery voltage using a result of the estimation, thereby controlling the battery 2 with high accuracy. The battery control apparatus 1 according to the present embodiment is configured to include a control unit 10, a voltage detection unit 11, a current detection unit 12, a battery temperature detection unit 13, and a storage unit 14, as shown in FIG. 1.

The voltage detection unit 11 detects a voltage between a positive electrode and a negative electrode of the battery 2 as the battery voltage and outputs a result of the detection to the control unit 10. The current detection unit 12 detects a charging or discharging current flowing through the battery 2 and outputs a result of the detection to the control unit 10. The battery temperature detection unit 13 detects a surface temperature of the battery 2 or a temperature of a member or a space near the battery 2 as a battery temperature and outputs a result of the detection to the control unit 10.

The control unit 10 has functional blocks including a charge and discharge amount calculation unit 101, a ΔOCV estimation unit 102, and a battery management unit 103. The control unit 10 is constructed using, for example, a microcomputer, and can implement the functional blocks by executing a predetermined program. Note that the control unit 10 may be constructed using, for example, a logic circuit, such as an FPGA (Field Programmable Gate Array) instead of the microcomputer.

The charge and discharge amount calculation unit 101 calculates a charge or discharge amount of the battery 2 on the basis of a result of detecting a charging or discharging current which is input from the current detection unit 12. The ΔOCV estimation unit 102 estimates ΔOCV representing an amount of decrease in an open-circuit voltage (OCV) of the battery 2 due to a memory effect on the basis of charge and discharge amounts calculated by the charge and discharge amount calculation unit 101. Note that specific details of the processes will be described later.

The battery management unit 103 is a portion which controls and manages the battery 2 and, for example, performs charge and discharge control of the battery 2 on the basis of a charge or discharge instruction from the outside and obtains a state of charge (SOC) of the battery 2. Specifically, the battery management unit 103 corrects a result of detecting the OCV which is input from the voltage detection unit 11 when the battery 2 is neither in a state of being charged nor in a state of being discharged on the basis of a value of ΔOCV estimated by the ΔOCV estimation unit 102 and obtains an original value of the OCV of the battery 2 in the absence of a memory effect. The battery management unit 103 calculates the SOC that is an expression of the state of charge of the battery 2 as a value of 0 to 100% on the basis of the value of the OCV after the correction and results of detecting charging and discharging currents and the battery temperature which are input from the current detection unit 12 and the battery temperature detection unit 13, respectively, and notifies the outside of a result of the calculation. At this time, the battery management unit 103 may further perform charge and discharge control of the battery 2 on the basis of a value of the calculated SOC as needed. For example, if the value of the SOC is close to 0%, the battery management unit 103 forcibly charges the battery 2 regardless of the presence or absence of a charge or discharge instruction. The battery 2 can be controlled and managed by an arbitrary method other than this.

The storage unit 14 is constructed using a storage medium, such as a RAM or a flash memory, and stores various types of information used in processing by the control unit 10. For example, charge and discharge amounts of the battery 2 which are calculated by the charge and discharge amount calculation unit 101, ΔOCV estimated by the ΔOCV estimation unit 102, and the like are stored in the storage unit 14. The control unit 10 can implement the functional blocks including the charge and discharge amount calculation unit 101, the ΔOCV estimation unit 102, and the battery management unit 103 described earlier by reading or writing the pieces of information from or to the storage unit 14.

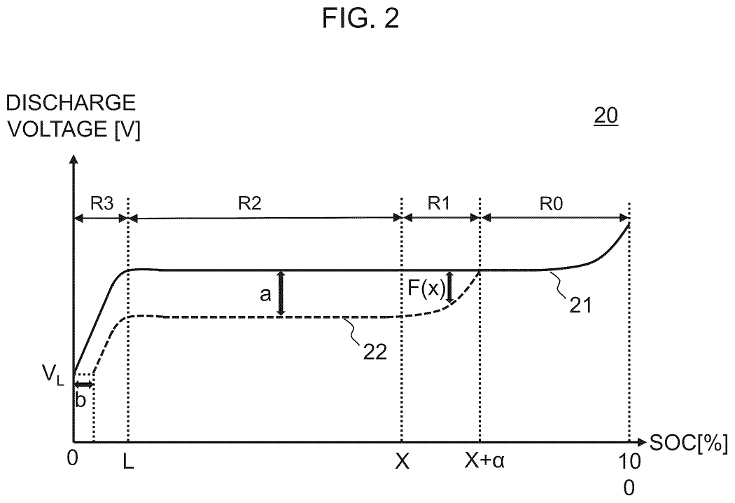

A ΔOCV estimation method in the battery control apparatus 1 will be described with reference to FIG. 2. FIG. 2 is a chart showing an outline of decrease in the battery voltage due to a memory effect. In FIG. 2, a graph 21 indicated by a solid line shows one example of a relationship between the SOC and a discharge voltage of the battery 2 in the absence of a memory effect. A graph 22 indicated by a broken line shows one example of the relationship between the SOC and the discharge voltage of the battery 2 in the presence of a memory effect. In each of these graphs 21 and 22, the horizontal axis represents a value [%] of the SOC of the battery 2 while the vertical axis represents the discharge voltage [V] of the battery 2.

In FIG. 2, a value of the SOC of the battery 2 at the end of a last discharge is indicated by X. When a value of the SOC approaches X while the battery 2 is discharging, ΔOCV arises under the influence of a memory effect, and a discharge voltage in the graph 22 becomes gradually lower than in the graph 21. When the value of the SOC becomes lower than X, a value of ΔOCV becomes a constant value a. When discharge proceeds further, and the value of the SOC becomes lower than a predetermined value L, the discharge voltage is known to decrease rapidly toward a discharge cutoff voltage V_{L}.

Letting X+α be a value of the SOC at which ΔOCV starts to appear under the influence of a memory effect, the graph 22 can be divided into the following four areas in accordance with the value of the SOC, on the basis of how the discharge voltage changes.
Area R0 (X+α≤SOC≤100)
   An area which is free from a memory effect and where ΔOCV=0.
Area R1 (X≤SOC≤X+α)
   An area where the value of ΔOCV increases gradually in accordance with a function F(x) under the influence of a memory effect.
Area R2 (L≤SOC≤X)
   An area where the discharge voltage is generally constant and the value of ΔOCV is the constant value a under the influence of the memory effect.
Area R3 (0≤SOC≤L)
   An area where the discharge voltage decreases rapidly toward the discharge cutoff voltage V_{L} while the value of ΔOCV remains at the constant value a.

Note that a value of the function F(x) and the value of a described above are values quantitatively showing a change in crystal structure due to a memory effect. The values change depending on the number of times that the battery 2 is repeatedly charged and discharged with an intermediate depth. Since a difference b in SOC between the graph 21 and the graph 22 when the discharge voltage becomes the discharge cutoff voltage VI, in the area R3 is a very small value with respect to a range which can be covered by the SOC of the battery 2, the difference b is neglected in the present embodiment.

The battery control apparatus 1 according to the present embodiment judges, from a value of the SOC of the battery 2, which one of the above-described areas R0 to R3 a current charge/discharge status of the battery 2 belongs to and switches a ΔOCV estimation method in accordance with a result of the judgment. This makes it possible to accurately estimate a value of ΔOCV even if the charge/discharge status of the battery 2 changes.

Note that although the ΔOCV estimation method is switched in accordance with a value of the SOC of the battery 2 in the above description, similar processing can be performed using a remaining capacity of the battery 2. In this case, a value of the remaining capacity of the battery 2 at the end of a last discharge may be used instead of X, and a value of the remaining capacity at which ΔOCV starts to appear under the influence of a memory effect may be used instead of X+α.

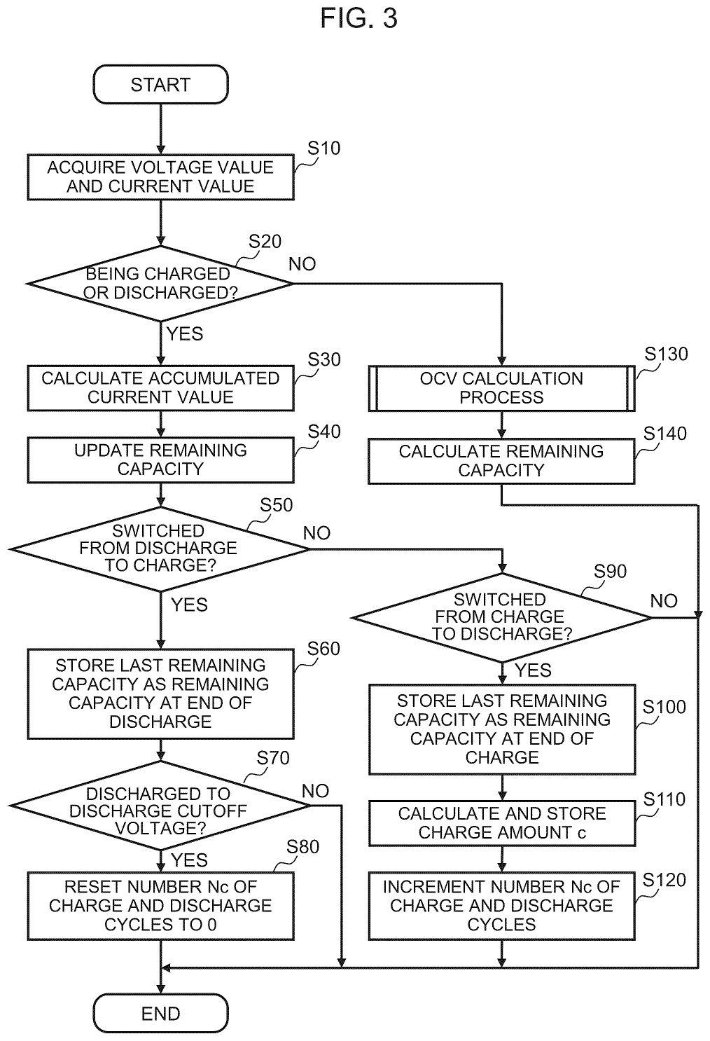

FIG. 3 is a flowchart showing the flow of a process by the battery control apparatus according to the one embodiment of the present invention. The battery control apparatus 1 manages the battery 2 by execution of the process shown in the flowchart in FIG. 3 at predetermined processing intervals by the control unit 10.

In step S10, the control unit 10 acquires a voltage value and a current value of the battery 2 from the voltage detection unit 11 and the current detection unit 12, respectively.

In step S20, the control unit 10 judges, on the basis of the current value acquired in step S10, whether the battery 2 is being charged or discharged. If the current value is not 0, the control unit 10 judges that the battery 2 is being charged or discharged and advances to step S30. If the current value is 0, the control unit 10 judges that the battery 2 is neither being charged nor discharged and advances to step S130.

In step S30, the control unit 10 calculates an accumulated current value during a period from the process last time to the process this time by means of the charge and discharge amount calculation unit 101. In this step, the accumulated current value can be calculated by, for example, multiplying the current value acquired in step S10 by the predetermined processing interval. Alternatively, the accumulated current value may be calculated by acquiring a current value a plurality of times at predetermined sampling intervals during one processing period, and multiplying the current values by the sampling interval and adding up result values. Note that it is preferable to set the sign of an accumulated current value to minus on a discharge side and set the sign of an accumulated current value to plus on a charge side such that an accumulated current value on the discharge side and an accumulated current value on the charge side are distinguishable from each other.

In step S40, the control unit 10 updates the remaining capacity of the battery 2 on the basis of the accumulated current value calculated in step S30. In this step, the control unit 10 adds or subtracts the accumulated current value calculated in step S30 to or from a remaining capacity obtained in the process last time. With this operation, the control unit 10 reflects the accumulated current value during the period from the process last time to the process this time and updates the remaining capacity of the battery 2 with a latest value.

In step S50, the control unit 10 judges whether the charge/discharge status of the battery 2 has been switched from discharge to charge. In this step, the control unit 10, for example, compares the sign of a current value acquired in the process last time with the sign of a current value acquired in the process this time. If a result of the comparison indicates that the sign of the current value last time is minus representing discharge and that the sign of the current value this time is plus representing charge, the control unit 10 judges that the charge/discharge status of the battery 2 has been switched from discharge to charge and advances to step S60. Note that switching from discharge to charge here includes a case where the charge/discharge status has been switched from discharge to charge via a charge- and discharge-stop state (a state with a current value of 0). On the other hand, if the sign of the current value last time is not minus or if the sign of the current value this time is not plus, the control unit 10 judges that the charge/discharge status of the battery 2 has not been switched from discharge to charge and advances to step S90.

In step S60, the control unit 10 stores the last remaining capacity of the battery 2 updated in step S40 as a remaining capacity at the end of the discharge in the storage unit 14. Note that the remaining capacity at the end of the discharge to be stored here is used in a process in step S110 (to be described later).

In step S70, the control unit 10 judges whether the battery 2 has been discharged to the discharge cutoff voltage. In this step, the control unit 10 judges, for example, whether the current value acquired in step S10 in the process last time coincides with the discharge cutoff voltage VI, described earlier with reference to FIG. 2. If the current value coincides, the control unit 10 judges that the battery 2 has been discharged to the discharge cutoff voltage and advances to step S80. On the other hand, if the current value does not coincide, the control unit 10 judges that the battery 2 has not been discharged to the discharge cutoff voltage and ends the process shown in the flowchart in FIG. 3.

In step S80, the control unit 10 resets the number Ne of charge and discharge cycles of the battery 2 to 0 that is an initial value. Note that the number Nc of charge and discharge cycles of the battery 2 is stored in the storage unit 14 and is incremented by one each time the charge/discharge status of the battery 2 is switched from charge to discharge. When the number Nc of charge and discharge cycles of the battery 2 is reset to 0 in step S80, the control unit 10 ends the process shown in the flowchart in FIG. 3.

In step S90, the control unit 10 judges whether the charge/discharge status of the battery 2 has been switched from charge to discharge. In this step, the control unit 10, for example, compares the sign of the current value acquired in the process last time with the sign of the current value acquired in the process this time, as in step S50 described earlier. If a result of the comparison indicates that the sign of the current value last time is plus representing charge and that the sign of the current value this time is minus representing discharge, the control unit 10 judges that the charge/discharge status of the battery 2 has been switched from charge to discharge and advances to step S100. Note that switching from charge to discharge here includes a case where the charge/discharge status has been switched from charge to discharge via the charge- and discharge-stop state (a state with a current value of 0). On the other hand, if the sign of the current value last time is not plus or if the sign of the current value this time is not minus, the control unit 10 judges that the charge/discharge status of the battery 2 has not been switched from charge to discharge and ends the process shown in the flowchart in FIG. 3. In this case, the battery 2 has been charging or discharging since the process last time.

In step S100, the control unit 10 stores the remaining capacity of the battery 2 updated in the last step S40 as a remaining capacity at the end of the charge in the storage unit 14.

In step S110, the control unit 10 calculates a charge amount c of the battery 2 which is obtained through this charge by means of the charge and discharge amount calculation unit 101. In this step, the control unit 10 calculates a difference between the remaining capacity at the end of the most recent charge that is stored in the storage unit 14 in step S100 and a remaining capacity at the end of a most recent discharge which is stored in the storage unit 14 in step S60 and sets the difference as the charge amount c of the battery 2. The control unit 10 stores the calculated charge amount c in the storage unit 14.

In step S120, the control unit 10 increments the number Nc of charge and discharge cycles of the battery 2 stored in the storage unit 14 by one. With this step, the number Nc of charge and discharge cycles of the battery 2 is incremented by one each time the charge/discharge status of the battery 2 is switched from charge to discharge. When the number Nc of charge and discharge cycles after the increment is stored in the storage unit 14 to update the number Ne of charge and discharge cycles, the control unit 10 ends the process shown in the flowchart in FIG. 3.

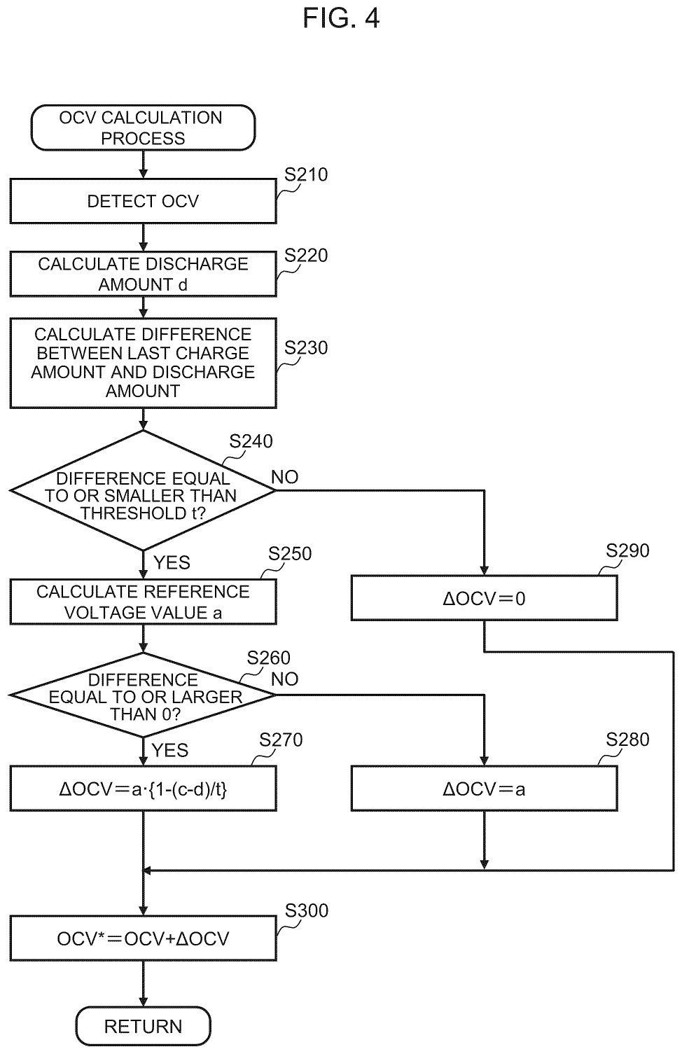

In step S130, the control unit 10 performs an OCV calculation process by means of the charge and discharge amount calculation unit 101, the ΔOCV estimation unit 102, and the battery management unit 103. The OCV calculation process estimates a value of ΔOCV by the method described earlier with reference to FIG. 2 and corrects a voltage value acquired in step S10 when the battery 2 is neither being charged nor discharged, i.e., a value of the OCV of the battery 2 on the basis of the estimated value of ΔOCV. With this correction, the influence of a memory effect is removed from the value of the OCV to obtain a value of the OCV commensurate with the remaining capacity of the battery 2. Note that details of the OCV calculation process to be performed in step S130 will be described later with reference to a flowchart in FIG. 4.

In step S140, the control unit 10 calculates, by means of the battery management unit 103, the remaining capacity of the battery 2 on the basis of the OCV after the correction that is obtained through the OCV calculation process in step S130. In this step, a remaining capacity corresponding to an OCV after correction can be obtained using, for example, a relational expression between an OCV set in advance and a remaining capacity. Note that a general relational expression between an OCV and a remaining capacity changes depending on operation conditions, such as the temperature of the battery 2 and the magnitude of a current immediately before OCV detection. For this reason, it is preferable to use different relational expressions between an OCV and a remaining capacity to be used in the process in step S140, depending on the battery temperature acquired from the battery temperature detection unit 13, the last current value acquired from the current detection unit 12, and the like. When the remaining capacity based on the OCV after the correction can be calculated, the control unit 10 ends the process shown in the flowchart in FIG. 3.

FIG. 4 is a flowchart showing the details of the OCV calculation process to be executed in step S130 of FIG. 3.

In step S210, the charge and discharge amount calculation unit 101 detects the OCV of the battery 2. In this step, the OCV of the battery 2 can be detected from a voltage value acquired in step S10 of FIG. 3 from the voltage detection unit 11.

In step S220, the charge and discharge amount calculation unit 101 calculates a discharge amount d of the battery 2 which is obtained through this discharge. In this step, the charge and discharge amount calculation unit 101 calculates a difference between a remaining capacity at the end of a most recent charge which is stored in the storage unit 14 in step S100 of FIG. 3 and a most recent remaining capacity updated in step S40 and sets the difference as the discharge amount d of the battery 2. The charge and discharge amount calculation unit 101 stores the calculated discharge amount d in the storage unit 14.

In step S230, the ΔOCV estimation unit 102 calculates a difference c-d between the last charge amount c stored in the storage unit 14 in step S110 of FIG. 3 and the discharge amount d calculated in step S220.

In step S240, the ΔOCV estimation unit 102 judges whether the difference c-d between the charge amount c and the discharge amount d that is calculated in step S230 is equal to or smaller than a predetermined threshold t. If the difference c-d is equal to or smaller than the threshold t, the ΔOCV estimation unit 102 advances to step S250. If the difference c-d is larger than the threshold t, the ΔOCV estimation unit 102 judges that the current charge/discharge status of the battery 2 belongs to the area R0 of the areas R0 to R3 described with reference to FIG. 2 and advances to step S290. The threshold t used in the judgment process in step S240 represents a limit of an area where a value of ΔOCV starts to increase gradually under the influence of a memory effect while the battery 2 is discharging, on the basis of the remaining capacity of the battery 2 at the end of a last discharge. This corresponds to the value a of the SOC defining a boundary between the area R0 and the area R1.

Note that the above-described threshold t can be set in advance in the battery control apparatus 1 on the basis of actual measurement data, a simulation result, and the like which are acquired beforehand using the battery 2. Specifically, it has turned out by experiments that a value of, for example, about 10 to 20 [Ah] (preferably 15 [Ah]) can be set as the threshold t.

In step S250, the ΔOCV estimation unit 102 calculates the reference voltage value a on the basis of a value of the number Nc of charge and discharge cycles stored in the storage unit 14. The reference voltage value a corresponds to a value of ΔOCV which is constant in the area R2 shown in FIG. 2. In this step, the ΔOCV estimation unit 102 computes the reference voltage value a by, for example, the following expression (1):

$$a = p \times Nc \qquad ( 1 )$$

In expression (1), p represents a predetermined coefficient, which corresponds to a ratio between the number Nc of charge and discharge cycles and the reference voltage value a. Note that, if the number Nc of charge and discharge cycles is equal to or larger than a predetermined reference number Nr (e.g., Nr=15), Nc is set to Nr to keep the reference voltage value a constant. The coefficient p can be set in advance in accordance with characteristics of the battery 2 and the like, and is, for example, 0.0033.

In step S260, the ΔOCV estimation unit 102 judges whether the difference c-d between the charge amount c and the discharge amount d that is calculated in step S230 is equal to or larger than 0. If the difference c-d is equal to or larger than 0, the ΔOCV estimation unit 102 judges that the current charge/discharge status of the battery 2 belongs to the area R1 and advances to step S270. On the other hand, if the difference c-d is smaller than 0, the ΔOCV estimation unit 102 judges that the current charge/discharge status of the battery 2 belongs to the area R2 or R3 and advances to step S280.

In step S270, the ΔOCV estimation unit 102 calculates ΔOCV on the basis of the difference c-d calculated in step S230, the threshold t used in the judgment process in step S240, and the reference voltage value a calculated in step S250 by the following expression (2):

$$Δ OCV = a \times \{ 1 - ( c - d ) / t \} \qquad ( 2 )$$

If the current charge/discharge status of the battery 2 belongs to the area R1, a value of ΔOCV under the influence of a memory effect can be calculated by expression (2) above. Note that expression (2) corresponds to the function F(x) described earlier.

In step S280, the ΔOCV estimation unit 102 calculates ΔOCV on the basis of the reference voltage value a calculated in step S250 by the following expression (3):

$$Δ OCV = a \qquad ( 3 )$$

If the current charge/discharge status of the battery 2 belongs to the area R2 or R3, a value of ΔOCV under the influence of a memory effect can be calculated by expression (3) above. That is, a value of ΔOCV can be calculated as the constant value a commensurate with the number Nc of charge and discharge cycles in these areas.

In step S290, the ΔOCV estimation unit 102 calculates ΔOCV by the following expression (4):

$$Δ OCV = 0 \qquad ( 4 )$$

If the current charge/discharge status of the battery 2 belongs to the area R0, since a memory effect has no influence, a value of ΔOCV can be calculated to be 0 by expression (4) above.

When the value of ΔOCV can be calculated in step S270, S280, or S290, the flow advances to step S300. In step S300, the battery management unit 103 corrects a value of the OCV detected in step S210 on the basis of the calculated value of ΔOCV in accordance with the following expression (5) to calculate OCV* representing the value of the OCV after the correction:

$${OCV}^{*} = OCV + Δ OCV \qquad ( 5 )$$

When OCV* can be calculated as the OCV after the correction in step S300, the control unit 10 ends the OCV calculation process shown in the flowchart in FIG. 4 and advances to step S140 in FIG. 3.

The above-described embodiment of the present invention has the following operation and effects.
(1) The battery control apparatus 1 includes the voltage detection unit 11 that detects the open-circuit voltage (OCV) of the battery 2 that is a secondary battery when the battery 2 is discharged after being charged and the control unit 10 that estimates the amount ΔOCV of decrease in OCV due to a memory effect on the basis of a charge and discharge history of the battery 2. This configuration makes it possible to control the battery 2 with high accuracy even if a memory effect occurs.
(2) The control unit 10 estimates ΔOCV on the basis of the charge amount c of the battery 2 that is obtained through a charge and the discharge amount d of the battery 2 that is obtained through a discharge. Specifically, the control unit 10 calculates the difference c-d between the charge amount c and the discharge amount d (step S230) and estimates ΔOCV on the basis of the difference c-d (steps S240 to S290). This makes it possible to accurately estimate ΔOCV in accordance with the current charge/discharge status of the battery 2.
(3) The control unit 10 estimates ΔOCV on the basis of the number Ne of charge and discharge cycles of the battery 2 if the difference c-d between the charge amount c and the discharge amount d is equal to or smaller than the threshold t (YES in step S240). Specifically, the control unit 10 estimates ΔOCV (step S270) on the basis of the reference voltage value a based on the number Nc of charge and discharge cycles and a ratio of the difference c-d to the threshold t by expression (2) if the difference c-d is equal to or larger than 0 and equal to or smaller than the threshold t (YES in step S260) and estimates ΔOCV to be the reference voltage value a by expression (3) (step S280) if the difference c-d is smaller than 0 (NO in step S260). This makes it possible to accurately estimate a value of ΔOCV appearing under the influence of a memory effect.
(4) The control unit 10 sets a value obtained by multiplying the predetermined coefficient p by the number Ne of charge and discharge cycles as the reference voltage value a by expression (1) if the number Ne of charge and discharge cycles is equal to or smaller than the predetermined reference number Nr and keeps the reference voltage value a constant if the number Nc of charge and discharge cycles is larger than the reference number Nr (step S250). This makes it possible to accurately obtain the reference voltage value a necessary for estimation of ΔOCV in view of the degree of influence of a memory effect that changes in accordance with the number Ne of charge and discharge cycles.
(5) The control unit 10 estimates a value of ΔOCV to be 0 by expression (4) (step S290) if the difference c-d between the charge amount c and the discharge amount d is larger than the threshold t (NO in step S240). This makes it possible to correctly estimate a value of ΔOCV to be 0 if a memory effect has no influence.
(6) The threshold t is, for example, 10 to 20 [Ah]. This makes it possible to accurately represent a limit of an area where a value of ΔOCV increases gradually under the influence of a memory effect.
(7) The control unit 10 resets the number Ne of charge and discharge cycles to 0 (step S80) if the battery 2 is discharged until a voltage of the battery 2 becomes the predetermined discharge cutoff voltage VI. (YES in step S70). This makes it possible to, if a refresh discharge that reduces the SOC of the battery 2 to 0% is performed, and thereby a decrease in OCV due to a memory effect is eliminated, correctly reflect the elimination in calculation of the reference voltage value a in later processing and obtain an accurate estimation result of ΔOCV.
(8) The battery 2 is, for example, a zinc secondary battery using nickel hydroxide for the positive electrode and zinc for the negative electrode. This makes it possible to enhance usability of a zinc secondary battery having a high energy density and a high degree of safety.

Note that the present invention is not limited to the above-described embodiment and can be carried out using an arbitrary constituent element without departing from the spirit thereof.

The above-described embodiment and modifications are merely examples, and the present invention is not limited to details of the embodiment and modifications unless features of the invention are impaired. Although various embodiments and modifications have been described above, the present invention is not limited to the details of the embodiments and modifications. Other aspects conceivable within the technical idea of the present invention are also included in the scope of the present invention.

What is claimed is:

1. A battery control apparatus comprising:
a voltage detection unit which detects an open-circuit voltage of a secondary battery when the secondary battery is discharged after being charged; and
a control unit which estimates an amount of decrease in the open-circuit voltage due to a memory effect on the basis of a charge and discharge history of the secondary battery.

2. The battery control apparatus according to claim 1, wherein
the control unit estimates the amount of decrease in the open-circuit voltage on the basis of a charge amount of the secondary battery which is obtained through the charge and a discharge amount of the secondary battery which is obtained through the discharge.

3. The battery control apparatus according to claim 2, wherein
the control unit calculates a difference between the charge amount and the discharge amount and estimates the amount of decrease in the open-circuit voltage on the basis of the difference.

4. The battery control apparatus according to claim 3, wherein
the control unit estimates the amount of decrease in the open-circuit voltage on the basis of the number of charge and discharge cycles of the second battery if the difference is equal to or smaller than a predetermined threshold.

5. The battery control apparatus according to claim 4, wherein
the control unit
estimates the amount of decrease in the open-circuit voltage on the basis of a reference voltage value based on the number of charge and discharge cycles and a ratio of the difference to the threshold if the difference is equal to or larger than 0 and equal to or smaller than the threshold, and
estimates the amount of decrease in the open-circuit voltage to be the reference voltage value if the difference is smaller than 0.

6. The battery control apparatus according to claim 5, wherein
if the difference is equal to or larger than 0 and equal to or smaller than the threshold, the control unit estimates the amount of decrease in the open-circuit voltage on the basis of the following expression:
ΔOCV=a×{1−(c−d)/t}
where ΔOCV is the amount of decrease in the open-circuit voltage, a is the reference voltage value, c is the charge amount, d is the discharge amount, and t is the threshold.

7. The battery control apparatus according to claim 5, wherein
the control unit
sets, as the reference voltage value, a value obtained by multiplying a predetermined coefficient by the number of charge and discharge cycles if the number of charge and discharge cycles is equal to or smaller than a predetermined reference number, and
keeps the reference voltage value constant if the number of charge and discharge cycles is larger than the reference number.

8. The battery control apparatus according to claim 4, wherein
the control unit estimates the amount of decrease in the open-circuit voltage to be 0 if the difference is larger than the threshold.

9. The battery control apparatus according to claim 4, wherein
the threshold is 10 to 20 [Ah].

10. The battery control apparatus according to claim 4, wherein
the control unit resets the number of charge and discharge cycles to 0 when the secondary battery is discharged until a voltage of the secondary battery becomes a predetermined discharge cutoff voltage.

11. The battery control apparatus according to claim 1, wherein
the secondary battery is a zinc secondary battery using nickel hydroxide for a positive electrode and zinc for a negative electrode.

12. A battery control method comprising:
storing a charge and discharge history of a second battery;
detecting an open-circuit voltage of the secondary battery when the secondary battery is discharged after being charged;
estimating an amount of decrease in the open-circuit voltage due to a memory effect on the basis of the charge and discharge history of the secondary battery; and
controlling the secondary battery on the basis of the estimated amount of decrease in the open-circuit voltage.
